(19) United States
(12) Patent Application Publication
(10) Pub. No.: US 2007/0140511 A1
(43) Pub. Date: Jun. 21, 2007

(54) Process of implementing low frequency of audio signal

(75) Inventors: Yan Lin, Shenzhen (CN); Yaoliang Zhou, Shenzhen (CN); Pingri Guo, Shenzhen (CN)

Correspondence Address: Raymond Y. Chan, Suite 128, 108 N. Ynez Avenue, Monterey Park, CA, 91754, US

(73) Assignee: Shenzhen LANGUANG Electronic Industrial Corporation

(21) Appl. No.: 11/521,751

(22) Filed: Sep. 15, 2006

(30) Foreign Application Priority Data
Dec. 20, 2005 (CN) 200510121069.0

(51) Int. Cl. H03G 5/00; H03G 3/00

(52) U.S. Cl. 381/98; 381/61

(57) ABSTRACT

A process of implementing a low frequency of an audio signal includes the steps of collecting a fundamental frequency from the audio signal at a low frequency region thereof, generating a controlled 2^{nd} harmonic, a controlled 3^{rd} harmonic, and a controlled 4^{th} harmonics respectively based on a 2^{nd} harmonic, a 3^{rd} harmonic, and a 4^{th} harmonic in responsive to the fundamental frequency, and generating a final output signal from a combination of the controlled 2^{nd} harmonic, the controlled 3^{rd} harmonic, and the controlled 4^{th} harmonic. In which, the output signal is generated correlating with a loudness of the fundamental frequency to enhance the bass performance of an audio system device.

### BACKGROUND OF THE PRESENT INVENTION

1. Field of Invention

The present invention relates to a device and method of implementing low frequencies of an audio signal to enhance the bass performance of an audio system device.

2. Description of Related Arts

People usually like to judge the quality of the audio system device by their bass performances. However, due to restriction on dimension and manufacture cost and such, their bass performances are not satisfactory. Conventional method of enhancing the bass performance of an audio system is to increase the power of the low frequency signal. However, this method brings along many problems such as overloading on the amplifier which lowers the overall quality of the sound. For a small audio system device in particular, these problems can lead to a physical damage to the speakers.

It is known that even when the audio signal does not include a specific fundamental frequency, people can still clearly determine the tone of the fundamental frequency as long as an effective sequence of harmonics exists. According to that theory, a technique has been developed and used to process the transformation process between the low frequency signal and the harmonics. Therefore, the quality of the harmonic signal output through a speaker system is better than that of the low frequency signal through the speaker system. Until now, conventional method uses the combination of generating the harmonics about 10 times or more consecutively to replace the fundamental frequency. A feedback multiplication and full-wave rectification methods are used to generate the harmonics. The disadvantage of this method is that it is hard to control the power for different order harmonics. In addition, the accuracy is relatively low, thus, the output bass performance quality is unsatisfactory. There are other existing methods that help to strengthen the bass performance of the audio system device theoretically, however, these methods experiences hardware physical difficulties in accomplishing such objects.

### SUMMARY OF THE PRESENT INVENTION

A main object of the present invention is to provide a process of enhancing the bass performance of an audio system which can be easily embodied by an audio hardware to overcome the existing method.

Another object of the present invention is to provide a simple audio system device which can enhance the bass performance and overcome the problems of using a complicated audio system.

Accordingly, in order to accomplish the above objects, the present invention provides a process of implementing a low frequency of an audio signal, comprising the steps of:

(a) collecting a fundamental frequency from the audio signal at a low frequency region thereof;

(b) deriving a first control signal in responsive to dynamirange of the fundamental frequency;

(c) generating a 2^{nd} harmonic, a 3^{rd} harmonic, and a 4^{th} harmonic correlating with the fundamental frequency;

(d) generating a controlled 2^{nd} harmonic, a controlled 3^{rd} harmonic, and a controlled 4^{th} harmonic respectively based on the 2^{nd} harmonic, the 3^{rd} harmonic, and the 4^{th} harmonic in responsive to the first control signal; and

(e) generating a final output signal from a combination of the controlled 2^{nd} harmonic, the controlled 3^{rd} harmonic, and the controlled 4^{th} harmonic, wherein the final output signal is correlating with a loudness of the fundamental frequency.

The present invention further comprises an audio enhancing system for enhancing an audio signal at a low frequency region, comprising:

a first filtering device filtering out a low frequency signal from the audio signal to obtain a fundamental frequency from the audio signal at a low frequency region thereof;

an automatic gain control module generating a first control signal, wherein a 2^{nd} harmonic, a 3^{rd} harmonic, and a 4^{th} harmonic are generated correlating with the fundamental frequency;

first means for processing the 2^{nd} harmonic, a 3^{rd} harmonic, and a 4^{th} harmonic to generate a controlled 2^{nd} harmonic, a controlled 3^{rd} harmonic, and a controlled 4^{th} harmonic respectively based on the ₂nd harmonic, the 3^{rd} harmonic, and the 4^{th} harmonic in responsive to the first control signal; and

second means for generating a final output signal from a combination of the controlled 2ⁿ harmonic, the controlled 3^{rd} harmonic, and the controlled 4^{th} harmonic, wherein the final output signal is correlating with a loudness of the fundamental frequency.

These and other objectives, features, and advantages of the present invention will become apparent from the following detailed description, the accompanying drawings, and the appended claims.

### BRIEF DESCRIPTION OF THE DRAWINGS

FIG. 1 is a block diagram illustrating the process of implementing a low frequency of an audio signal according to a preferred embodiment of the present invention.

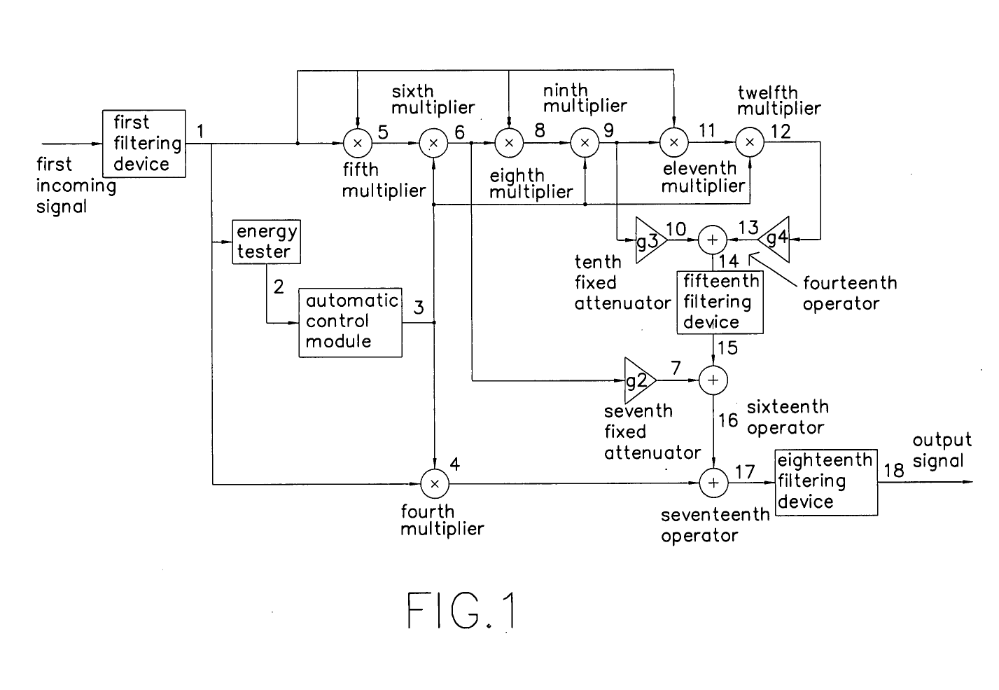

### DETAILED DESCRIPTION OF THE PREFERRED EMBODIMENT

The method of the present invention transforms fundamental frequencies of a low frequency region to become an output signal formed by a combination of a 2^{nd}, 3^{rd} and 4^{th} harmonic which correlates with a loudness of the fundamental frequencies.

Accordingly the present invention provides a process of implementing a low frequency of an audio signal, comprising the following steps.

(1) Collect a fundamental frequency from the audio signal at a low frequency region thereof.

(2) Derive a first control signal in responsive to dynamirange of the fundamental frequency.

(3) Generate a 2^{nd} harmonic, a 3^{rd} harmonic, and a 4^{th} harmonic correlating with the fundamental frequency.

(4) Generate a controlled 2^{nd} harmonic, a controlled 3^{rd} harmonic, and a controlled 4^{th} harmonic respectively based on the 2^{nd} harmonic, the 3^{rd} harmonic, and the 4^{th} harmonic in responsive to the first control signal.

(5) Generate a final output signal from a combination of the controlled 2^{nd} harmonic, the controlled 3^{rd} harmonic, and the controlled 4^{th} harmonic, wherein the final output signal is correlating with a loudness of the fundamental frequency.

The present invention further comprises an audio enhancing system for enhancing an audio signal at a low frequency region, comprising a first filtering device and an automatic gain control module (AGC module).

The first filtering device is arranged for filtering out a low frequency signal from the audio signal to obtain a fundamental frequency from the audio signal at a low frequency region thereof.

The automatic gain control module generates a first control signal, wherein a 2^{nd} harmonic, a 3^{rd} harmonic, and a 4^{th} harmonic are generated correlating with the fundamental frequency.

The audio enhancing system further comprises first means for processing the 2^{nd} harmonic, a 3^{rd} harmonic, and a 4^{th} harmonic to generate a controlled 2^{nd} harmonic, a controlled 3^{rd} harmonic, and a controlled 4^{th} harmonic respectively based on the 2^{nd} harmonic, the 3^{rd} harmonic, and the 4^{th} harmonic in responsive to the first control signal, and second means for generating a final output signal from a combination of the controlled 2nd harmonic, the controlled 3^{rd} harmonic, and the controlled 4^{th} harmonic, wherein the final output signal is correlating with a loudness of the fundamental frequency.

In order to accurately control the energy of the harmonics, a filtration process is performed to eliminate non members of the 3^{rd} and 4^{th} harmonics before the combination of the 3^{rd} and 4th harmonics and the 2nd harmonic.

In order to achieve a satisfactory loudness combination and to accurately control the energy of the different harmonics, a relationship of a dynamic energy correlation is defined. It uses db (decibel) as a unit for measuring energy of the fundamental frequency and harmonics. When the fundamental frequency is within 300Hz, an energy dynamirange of the 2^{nd} harmonic is about 1˜1.5 times of the fundamental frequency. An energy dynamirange of the 3^{rd} harmonic is about 1.5˜2 times of the fundamental frequency. An energy dynamirange of the 4^{th} harmonic is about 2˜2.5 times of the fundamental frequency.

Both relationships described above are confirmed by repeatedly laboratory testing and data. The analysis is as the following.

In order to achieve a satisfactory bass performance from the audio system device, the different harmonics need to replace the fundamental frequency and at the same time, the loudness between the different harmonics and the fundamental frequency must match. The hearings of human ears are used to judge the matching performance the loudness.

According to a study of loudness characteristic curves, two important findings can be found within the low frequency range (within 800Hz). The first finding is that the loudness must be balanced at a certain level when within a certain amount of frequency region. Therefore, more energy is required when the frequency gets lower. The second finding is that the change of the energy is smaller in a low frequency region when the loudness changes from one level to another.

The above two findings are found based on the research studies data. Because the present invention mainly focuses in the low frequency region mainly below 200 Hz, therefore the 4^{th} harmonic range would be around 800 Hz at most. According to the study of loudness characteristic curves, a loudness correlation can be represented as an inclined linear line when a frequency region is within 30-800 Hz. For example, if the fundamental frequency is 100 Hz, then the energy (sound pressure level) would be about 40 db. Therefore if we need to keep the same loudness for the 2 dharmonic (200 Hz) and the fundamental frequency, we will require about 20 db. For the 3^{rd} harmonic (300 Hz), we will require 12 db. And for the 4^{th} harmonic, we will require 8 db. A constant control signal is used to multiply so as to match the loudness and meet the requirement.

Another important correlation between the different harmonics and the fundamental frequency is a dynamic relationship between them. It is known that the energy of audio signal is dynamic. Therefore, the energy of different harmonics required to replace the fundamental frequency will need to vary accordingly as well to maintain the same level of loudness. According to the study of loudness characteristic curves, if the energy of a 100 Hz signal is increased to 10 db, the loudness will increase respectively as well. Therefore, if we wish to maintain the same loudness level for the 2^{nd} harmonic (200 Hz), then it will require about 15 db. Accordingly, the 3^{rd} harmonic will require about 2 0db and the 4^{th} harmonic will require about 25 db.

In order to achieve a natural and soft bass performance enhancement, we also need to focus on the frequency region that is outside of a working region of the audio system device as a transitional signal. For example, if the performance of audio system device below the 100 Hz is unsatisfactory, we can setup a cut-off point at 100 Hz and use a combination of different harmonics to replace. In reality, low frequency signal comes from the filtering of the audio signal. If the cut-off point is set at 100 Hz, then that means the low frequency signal will include some of the signals from above 100 Hz after the attenuating process. These signals are important as well and should not be ignored. The present invention uses the automatic gain control process to process such transitional signal and can effectively enhance the bass performance.

The present invention provides an audio system device which can enhance the bass performance comprising the following elements in details.

(a) A first filtering device 1 is used to receive a first incoming signal and then filter out the low frequency signal that is needed to become a final output signal. The first filtering device 1 uses a 4^{th} order bandpass IIR filter which has a predetermined upper passband cut-off point and a lower passband cut-off point which is set at half of the upper passband cut-off point value. For example, if the upper passband cut-off point is set at 160 Hz, then the lower passband cut-off point is 80 Hz. The first filtering device 1 of the preferred embodiment uses an attenuation level of 12˜24 db/oct.

(b) An energy detector 2 is used to detect an energy level of the output signal coming out from the first filtering device 1 and then send it to the automatic gain control module 3. The prefer embodiment uses an envelope detector to characterize the energy of signals as envelope signals. A smooth envelope signal is desired in this process and therefore, a 2^{nd} order IIR filter is used to smoothen the signal.

(c) An automatic gain control module 3 is used to comply with the envelope signal according to a mathematical relation to form a first and second control signal. The first control signal is applied to control the dynamic energy of the 2^{nd}, 3^{rd}, and 4^{th} harmonic. The second control signal is applied to signals that fall in the range upon the upper passband cut-off point of the first filtering device 1. Therefore, the first and second control signals could be based on four different calculations to control the energy dynamiranges of the 2^{nd}, 3^{rd}, and 4^{th} harmonics so as to minimize error thereof. However, it is desired to use one single calculation to produce the control signals as it requires less hardware processes. According to the preferred embodiment, we will limit the ratio of the dynamic energy of the 2^{nd}, 3^{rd}, and 4^{th} harmonics with respect to the fundamental frequency. We can set these 3 values as 2-a, 3-a, 4-a. The automatic gain control module 3 will complete the calculations, an inputting signal is x, an outputting signal is y, a calculation is based on:

y=x^{-a}

In addition, if the inputting signal x is less than a value, for example 0.01, then the outputting signal y will be replaced by some constant values. When a=0.5, then according to the preferred embodiment, the control signals for the 2^{nd}, 3^{rd}, and 4^{th} harmonics can be accurately calculated as 1.5, 2, and 2.5 times of the fundamental frequency.

(d) A fourth multiplier 4 is used to multiply the output signal from the first filtering device 1 and the first control signal from the automatic gain control module 3 together to form a multiplied signal. In the case of the preferred embodiment, when a=0.5, the dynamirange of the multiplied signal from the fourth multiplier 4 should be half of the original. Thus, the fourth multiplier 4 acts like a compressor as well.

(e) A fifth multiplier 5 is used to self-multiply the output signal from the first filtering device 1 to form a first output signal. The first output signal includes the 2^{nd} harmonic, wherein the dynamirange of the 2^{nd} harmonic is double the amount of the output signal from the first filtering device 1.

(f) A sixth multiplier 6 is used to multiply the first output signal from the fifth multiplier 5 and the first control signal from the automatic gain control module 3 to form a second output signal so as to control the energy of the dynamirange of the 2^{nd} harmonic. This process ultimately deduces the dynamirange outputted from the fifth multiplier 5, wherein the dynamirange of the 2^{nd} harmonic is 1.5 times of the fundamental frequency (when a=0.5).

(g) A seventh fixed attenuator g2 7 is used to control the second output signal from the sixth multiplier 6 and produce the 2^{nd} harmonic which controlled by fixed and time-varying gain.

(h) An eighth multiplier 8 is used to multiply the fundamental frequency and the second output signal from the sixth multiplier to from a third output signal. The third output signal mainly includes the fundamental frequency and the 3^{rd} harmonic. Because the dynamirange of the 2^{nd} harmonic is 1.5 times of the fundamental frequency, therefore the dynamirange of the 3^{rd} harmonic outputted by the eighth multiplier 8 is 2.5 times of the fundamental frequency.

(i) A ninth multiplier 9 is used to multiply the third output signal from the eighth multiplier 8 and the first control signal from the automatic gain control module 3 to form a fourth output signal so as to control the energy of the dynamirange of the 3^{rd} harmonic to be 2 times of the fundamental frequency.

(j) A tenth fixed attenuator g3 10 is used to control the fourth output signal from the ninth multiplier 9 and produce the 3^{rd} harmonic which controlled by fixed and time-varying gain.

(k) An eleventh multiplier 11 is used to multiply the fundamental frequency and the fourth output signal from the ninth multiplier 9 to form a fifth output signal. The fifth output signal mainly includes the 2^{nd} and the 4^{th} harmonics. The 4^{th} harmonic is what we need, and because the dynamirange of the 3^{rd} harmonic is 2 times of the fundamental frequency, therefore the 4^{th} harmonic outputted by the eleventh multiplier 11 is 3 times of the fundamental frequency.

(l) A twelfth multiplier 12 is used to multiply the fifth output signal from the eleventh multiplier and the first control signal from the automatic gain control module 3 to form a sixth output signal so as to control the energy of the dynamirange of the 4^{th} harmonic to be 2.5 times of the fundamental frequency.

(m) A thirteenth fixed attenuator g4 13 is used to control the sixth output signal from the twelfth multiplier 12 and produce the 4^{th} harmonic which controlled by fixed and time-varying gain.

(n) A fourteenth operator 14 is used to add signals from the tenth and the thirteenth fixed attenuator g3 and g4 10, 13 together to form a seventh output signal which mainly includes the 2^{nd}, 3^{rd}, and 4^{th} harmonics and the fundamental frequency.

(o) A fifteenth filtering device 15 used to filter out the fundamental frequency and the 2^{nd} harmonic from seventh output signal of the fourteenth operator 14 to form an eighth output signal because we only need the 3^{rd} and the 4^{th} harmonics.

(p) A sixteenth operator 16 is used to add the signal from the seventh attenuator g2 7 and the eighth output signal from the fifteenth filtering device 15 together to form a ninth output signal. The ninth output signal mainly includes a combination signal which comprises of the 2^{nd}, 3^{rd}, and 4^{th} harmonics.

(q) A seventeenth operator 17 is used to add the multiplied signal from the fourth multiplier 4 and the combination signal from the sixteenth operator 16 to form a tenth output signal and is sent to an eighteenth filtering device 18.

(r) A eighteenth filtering device 18 used to:
i. filter out the low frequency signal mainly coming out from the fourth multiplier 4. In a small audio system, the low frequency signal is the problem that lowers the overall bass performance;
ii. filter out the unnecessary signals outputted by the seventh fixed attenuator g2 7;
iii. filter out frequency signals that are higher than the 4^{th} harmonic because it is possible that other harmonics can be formed from unnecessary inter-modulation.
iv. filter out high frequency noise.

The eighteenth filtering device 18 of the preferred embodiment uses a 4^{th} order IIR filter.

The present invention also provides a process of implementing low frequency of an audio signal comprising the following steps.

(1) Include all the low frequency signals that are needed after the first filtering device 1. Since the low frequency signals include fundamental frequencies that are needed to be treated.

(2) Self-multiply the fundamental frequency from the step (1) to form the 2^{nd} harmonic.

(3) Detect the energy level of the output signal coming out from the first filtering device 1 and then sending it to the automatic gain control module 3, wherein the automatic gain control module 3 complies with the envelop signal and the mathematical relation to form the first and second control signal. The first control signal is applied to control the energy of the 2^{nd}, 3^{rd}, and 4^{th} harmonics. The second control signal is applied to signals that fall in the range upon the upper passband cut-off of the first filtering device 1.

(4) Multiply the 2^{nd} harmonic by the first control signal from the automatic gain control module 3 to form the time-varying gain controlled 2^{nd} harmonic. Then the time-varying gain controlled 2^{nd} harmonic is then multiplied by the fundamental frequency from the step (1) to form the 3^{rd} harmonic. And, the time-varying gain controlled 2^{nd} harmonic is multiplied by fixed gain to form a controlled 2^{nd} harmonic.

(5) Multiply the 3^{rd} harmonic by the first control signal from the automatic gain control module 3 to form the time-varying gain controlled 3^{rd} harmonic. Then the time-varying gain controlled 3^{rd} harmonic is then multiplied by the fundamental frequency form the step (1) to form the 4^{th} harmonic. And, the time-varying gain controlled 3^{rd} harmonic is multiplied by fixed gain to form a controlled 3 harmonic.

(6) Multiply the 4^{th} harmonic and the first control signal from the automatic gain control module 3 to form the time-varying gain controlled 4^{th} harmonic. The time-varying gain controlled 4^{th} harmonic is multiplied by fixed gain to form a controlled 4^{th} harmonic.

(7) Add the controlled 3^{rd} harmonic from the step (5) with the controlled 4^{th} harmonic from the step (6) to form a first transitional output signal.

(8) Filter out the frequency corresponding to the fundamental frequency and the 2^{nd} harmonic from the first transitional output signal to form a second transitional output signal which is then added to the controlled 2^{nd} harmonic from the step (4) to form a third transitional output signal. In other words, the frequency, which is the same as the fundamental frequency and the 2nd harmonic, from the first transitional output signal is filtered out to form the second transitional output.

(9) Multiply the low frequency signal from the step (1) by the first control signal from the automatic gain control module 3 to form a controlled low frequency signal which is then added to the third transitional output signal from the step (4) to form a fourth transitional output signal.

(10) Filter the fourth transitional output signal through a bandpass filter to form the final output signal. Accordingly, the fourth transitional output signal is filtered out the low frequency signal which under the cut-off point from the fourth multiplier 4, the unnecessary signals outputted by the seventh fixed attenuator g2 7, frequency signals that are higher than the 4^{th} harmonic, and high frequency noise from the fourth transitional output signal to form the final output signal.

One skilled in the art will understand that the embodiment of the present invention as shown in the drawings and described above is exemplary only and not intended to be limiting.

It will thus be seen that the objects of the present invention have been fully and effectively accomplished. It embodiments have been shown and described for the purposes of illustrating the functional and structural principles of the present invention and is subject to change without departure from such principles. Therefore, this invention includes all modifications encompassed within the spirit and scope of the following claims.

What is claimed is:

1. A process of implementing a low frequency region of an audio signal, comprising the steps of:
(a) collecting a fundamental frequency from said audio signal at a low frequency region thereof;
(b) deriving a first control signal in responsive to dynamirange of said fundamental frequency;
(c) generating a 2^{nd} harmonic, a 3^{rd} harmonic, and a 4^{th} harmonic correlating with said fundamental frequency;
(d) generating a controlled 2^{nd} harmonic, a controlled 3^{rd} harmonic, and a controlled 4^{th} harmonics respectively based on said 2^{nd} harmonic, said 3^{rd} harmonic, and said 4^{th} harmonic in responsive to said fundamental frequency; and
(e) generating a final output signal from a combination of said controlled 2^{nd} harmonic, said controlled 3^{rd} harmonic, and said controlled 4^{th} harmonic, wherein said final output signal is correlating with a loudness of said fundamental frequency.

2. The process, as recited in claim 1, wherein the step (c) further comprises the steps of:
(c.1) self-multiplying said fundamental frequency to form said 2^{nd} harmonic,
(c.2) multiplying said 2^{nd} harmonic by said first control signal to form a time-varying gain controlled 2^{nd} harmonic;
(c.3) multiplying said time-varying gain controlled 2^{nd} harmonic by said fundamental frequency to form said 3^{rd} harmonic;
(c.4) multiplying said 3^{rd} harmonic by said first control signal to form a time-varying gain controlled 3^{rd} harmonic;
(c.5) multiplying said time-varying gain controlled 3^{rd} harmonic by said fundamental frequency to form said 4^{th} harmonic;
(c.6) multiplying said 4^{th} harmonic by said first control signal to form a time-varying gain controlled 4^{th} harmonic.

3. The process as recited in claim 1 wherein, in the step (d), said controlled 2^{nd} harmonic, said controlled 3^{rd} harmonic, and said controlled 4^{th} harmonic are formed by processing said 2^{nd} harmonic, said 3^{rd} harmonic, and said 4h harmonic through an automatic gain control module.

4. The process as recited in claim 2 wherein, in the step (d), said controlled 2^{nd} harmonic, said controlled 3^{rd} harmonic, and said controlled 4^{th} harmonic are formed by processing said 2^{nd} harmonic, said 3^{rd} harmonic, and said 4^{th} harmonic through an automatic gain control module.

5. The process, as recited in claim 4, wherein the step (e) further comprises the steps of:
(e.1) adding said controlled 3^{rd} harmonic with said controlled 4^{th} harmonic to form a first transitional output signal;
(e.2) filtering out a frequency corresponding to said fundamental frequency and said 2^{nd} harmonic from said first transitional output signal to form a second transitional output signal, wherein said second transitional output signal is added to said controlled 2^{nd} harmonic to form a third transitional output signal;
(e.3) multiplying said low frequency by said first control signal to form a controlled low frequency, wherein said controlled low frequency is added to the said third transitional output signal to form a fourth transitional output signal; and
(e.4) filtering said fourth transitional output signal through a bandpass filter to form said final output signal.

6. The process as recited in claim 1 wherein, in the step (d), said controlled 2^{nd}, 3^{rd}, and 4^{th} harmonics are generated from said 2^{nd}, 3^{rd}, and 4^{th} harmonics by attenuation process to maintain said controlled 2^{nd}, 3^{rd}, and 4^{th} harmonics at the same level of loudness of said fundamental frequency.

7. The process as recited in claim 5 wherein, in the step (d), said controlled 2^{nd}, 3^{rd}, and 4^{th} harmonics are generated from said 2^{nd}, 3^{rd}, and 4^{th} harmonics by attenuation process to maintain said controlled 2^{nd}, 3^{rd}, and 4^{th} harmonics at the same level of loudness of said fundamental frequency.

8. The process, as recited in claim 1, wherein the step (b) further comprises a step of detecting an energy level of said fundamental frequency by an envelope signal detector to characterize said energy of said fundamental frequency as envelope signal so as to control said energy of each of said 2^{nd},3^{rd}, and 4^{th} harmonics.

9. The process, as recited in claim 7, wherein the step (b) further comprises a step of detecting an energy level of said fundamental frequency by an envelope signal detector to characterize said energy of said fundamental frequency as envelope signal so as to control said energy of each of said 2^{nd}, 3^{rd}, and 4^{th} harmonics.

10. The process, as recited in claim 1, further comprising the steps of:
setting a cut-off point to said fundamental frequency to collect a transitional signal which is out of said cut-off point;
generating a second control signal; and
processing said transitional signal with said second control signal to combine with said controlled 2^{nd}, 3^{rd}, and 4^{th} harmonics to form said final output signal.

11. The process, as recited in claim 9, further comprising the steps of:
setting a cut-off point to said fundamental frequency to collect a transitional signal which is out of said cut-off point;
generating a second control signal; and
processing said transitional signal with said second control signal to combine with said controlled 2^{nd}, 3^{rd}, and 4^{th} harmonics to form said final output signal.

12. The process, as recited in claim 1, wherein the steps (c) and (d) controls said energy of said fundamental frequency at a condition that when said fundamental frequency is within 300Hz, an energy dynamirange of said 2^{nd} harmonic is 1˜1.5 times of said fundamental frequency, an energy dynamirange of said 3^{rd} harmonic is 1.5˜2 times of said fundamental frequency, and an energy dynamirange of said 4^{th} harmonic is 2˜2.5 times of said fundamental frequency.

13. The process, as recited in claim 11, wherein the steps (c) and (d) controls said energy of said fundamental frequency at a condition that when said fundamental frequency is within 300 Hz, an energy dynamirange of said 2^{nd} harmonic is 1˜1.5 times of said fundamental frequency, an energy dynamirange of said 3^{rd} harmonic is 1.5˜2 times of said fundamental frequency, and an energy dynamirange of said 4^{th} harmonic is 2˜2.5 times of said fundamental frequency.

14. An audio enhancing system for enhancing a low frequency of an audio signal, comprising:
a first filtering device filtering out a low frequency signal from said audio signal to obtain a fundamental frequency from said audio signal at a low frequency region thereof;
an automatic gain control module generating a first control signal, wherein a 2^{nd} harmonic, a 3^{rd} harmonic, and a 4^{th} harmonic are generated correlating with said fundamental frequency;
first means for processing said 2^{nd} harmonic, a 3^{rd} harmonic, and a 4^{th} harmonic, wherein a controlled 2^{nd} harmonic, a controlled 3^{rd} harmonic, and a controlled 4^{th} harmonic are generated respectively based on said 2^{nd} harmonic, said 3^{rd} harmonic, and said 4^{th} harmonic in responsive to said fundamental frequency; and
second means for generating a final output signal from a combination of said controlled 2^{nd} harmonic, said controlled 3^{rd} harmonic, and said controlled 4^{th} harmonic, wherein said final output signal is correlating with a loudness of said fundamental frequency.

15. The audio enhancing system, as recited in claim 14, wherein said first means comprises a multiplier processing said fundamental frequency that said fundamental frequency is processed to self-multiply to form said 2^{nd} harmonic, said 2^{nd} harmonic is processed to multiply by said first control signal to form a time-varying gain controlled 2^{nd} harmonic, said time-varying gain controlled 2^{nd} harmonic is processed to multiply by said fundamental frequency to form said 3^{rd} harmonic, said 3^{rd} harmonic is processed to multiply by said first control signal to form a time-varying gain controlled 3^{rd} harmonic, and said time-varying gain controlled 3^{rd} harmonic is processed to multiply by said fundamental frequency to form said 4^{th} harmonic.

16. The audio enhancing system, as recited in claim 15, wherein said second means comprises a processor adding said controlled 3^{rd} harmonic with said controlled 4^{th} harmonic to form a first transitional output signal, a first filter filtering out said fundamental frequency and said 2^{nd} harmonic from said first transitional output signal to form a second transitional output signal, wherein said second transitional output signal is added to said controlled 2^{nd} harmonic to form a fourth transitional output signal, a multiplying processor multiplying said fundamental frequency by said first control signal to form a controlled fundamental frequency, wherein said controlled fundamental frequency is added to the said fourth transitional output signal to form a fifth transitional output signal, and a second filter filtering said fifth output signal through a bandpass filter to form said final output signal.

17. The audio enhancing system, as recited in claim 16, wherein said controlled 2^{nd}, 3^{rd}, and 4^{th} harmonics are generated from said 2 nd, 3^{rd}, and 4^{th} harmonics by attenuation process to maintain said controlled 2^{nd}, 3^{rd}, and 4^{th} harmonics at the same level of loudness of said fundamental frequency.

18. The audio enhancing system, as recited in claim 17, further comprises an envelope detector detecting an energy level of said fundamental frequency to characterize said energy of said fundamental frequency as envelope signal so as to control said energy of each of said 2^{nd}, 3^{rd}, and 4^{th} harmonics.

19. The audio enhancing system, as recited in claim 14, wherein said energy of said fundamental frequency is controlled at a condition that when said fundamental frequency is within 300 Hz, an energy dynamirange of said 2^{nd} harmonic is 1˜1.5 times of said fundamental frequency, an energy dynamirange of said 3^{rd} harmonic is 1.5˜2 times of said fundamental frequency, and an energy dynamirange of said 4^{th} harmonic is 2˜2.5 times of said fundamental frequency.

20. The audio enhancing system, as recited in claim 18, wherein said energy of said fundamental frequency is controlled at a condition that when said fundamental frequency is within 300 Hz, an energy dynamirange of said 2^{nd} harmonic is 1˜1.5 times of said fundamental frequency, an energy dynamirange of said 3^{rd} harmonic is 1.5˜2 times of said fundamental frequency, and an energy dynamirange of said 4^{th} harmonic is 2˜2.5 times of said fundamental frequency.
